(19) United States
(12) Patent Application Publication
(10) Pub. No.: US 2012/0168215 A1
(43) Pub. Date: Jul. 5, 2012

(54) CURABLE RESIN COMPOSITION

(75) Inventors: Touko Shiina, Saitama-ken (JP); Masao Arima, Saitama-ken (JP); Shuichi Yamamoto, Tokyo (JP); Masato Yoshida, Saitama-ken (JP)

(73) Assignee: TAIYO HOLDINGS CO., LTD, Nerima-ku, Tokyo (JP)

(21) Appl. No.: 13/393,659

(22) PCT Filed: Aug. 27, 2010
(86) PCT No.: PCT/JP2010/005301

§ 371 Date: Mar. 1, 2012

(30) Foreign Application Priority Data
Sep. 2, 2009 (JP) 2009-202598

(51) Int. Cl. H05K 1/00; B05D 3/06; C08K 3/30; B05D 5/00; C08L 63/10; C09D 163/10

(52) U.S. Cl. 174/258; 522/82; 524/423; 427/99.4; 427/510

(57) ABSTRACT

Provided is a curable resin composition which exhibits improved developability even in through holes and can suppress the generation of development residue and which can yield a cured product with excellent heat resistance and hardness. A curable resin composition which comprises a carboxyl-containing resin, a photopolymerization initiator, and barium sulfate that has been pretreated with a dispersant having an acid group and/or a dispersant having a block copolymer structure, a graft polymer structure, and/or a star polymer structure.

### TECHNICAL FIELD

The present invention relates to a curable resin composition to be used for, for example, a solder resist developable with a dilute aqueous alkali solution.

### BACKGROUND ART

Generally, for protection of the circuit of a printed wiring board, a solder resist layer is formed as the surface layer of the substrate. In order to form such a solder resist layer, alkali-developable solder resist compositions developable with dilute aqueous alkali solutions are widely used.

Usually, since many through holes are provided in a printed wiring board, when a solder resist composition is applied or laminated to a printed wiring board, the solder resist composition will flow into the through holes. The solder resist composition having flowed into the through holes cannot be removed within a time for developing a desired fine pattern, and therefore the development time is prolonged in order to remove the solder resist composition.

However, increase in development time leads to not only decreased productivity but also excessive attack by a dilute aqueous alkali solution. This may cause problems of not only undercutting in a desired fine pattern but also the difficulty of forming a pattern. In particular, such problems become more conspicuous because increase in the density and the number of layers of printed wiring boards and reduction in the diameter of through holes have been advanced due to recent reduction in the dimensions of electronic parts.

Then, methods for improving the developability of a solder resist composition have been studied. There are many reports that a solder resist composition primarily comprising a carboxyl group-containing epoxy acrylate obtainable by adding a polybasic acid anhydride to a reaction product of a novolac-type epoxy resin with acrylic acid is effective for improving the developability.

When using such a carboxyl group-containing epoxy acrylate for a solder resist composition, it is necessary to adjust the acid value thereof to relatively high in order to satisfactorily perform development using a dilute aqueous alkali solution. However, in using such a carboxyl group-containing epoxy acrylate with a relatively high acid value, problems such as blister and peeling of a cured product of a solder resist will arise during performing electroless gold plating.

On the other hand, there is a problem that if a time for heat drying a diluent is long after applying a solder resist composition to a printed wiring board or if the printed wiring board is left at rest for a long time after drying the diluent, unexposed portions are not developed with a dilute aqueous alkali solution, generating development residue (see, for example, Patent Literature 1). As a solution to this, a method of improving developability by using a slightly soluble epoxy resin as a diluent has been disclosed (see, for example, Patent Literature 2). From the viewpoint of developability of through holes, it cannot be said that such a method itself is sufficient enough.

Other probable factors to reduce the developability include a filler component contained in a solder resist composition. A filler component, especially an inorganic filler component, is contained for the purpose of suppressing cure shrinkage of a film and increasing adhesion property, hardness, heat resistance, and tackiness. As such an inorganic filler component, barium sulfate especially has been used widely because it is easy to control the particle diameter and it is inexpensive.

However, inorganic filler components such as barium sulfate easily gather in a lower part of a solder resist coating film due to their large specific gravity. Moreover, inorganic filler components gathering in a lower part of a solder resist coating film will prevent a dilute aqueous alkali solution from permeating to between a circuit formed on a printed wiring board and the solder resist coating film, this will cause the increase of development residue.

Such development residue can be reduced by reducing the amount of inorganic filler components contained in a solder resist composition or failing to use such inorganic filler components (see, for example, Patent Literature 3). However, it is impossible to obtain sufficient heat resistance or hardness in a cured coating film of the composition by such a technique, which will also cause increase of the price of a solder resist composition.

### CITATION LIST

### Patent Literature

PLT 1: Japanese Patent No. 1799319 (Claims)
PLT2: Japanese Patent Application Laid-Open No. H1-141904 A (Claims)
PLT 3: Japanese Patent Application Laid-Open No. 2008-209502 A

### SUMMARY OF THE INVENTION

### Technical Problem

An object of the present invention is to provide a curable resin composition which can improve developability of through holes and reduce development residue and which can afford good heat resistance and good hardness to its cured product.

### Solution to Problem

According to one embodiment of the present invention, provided is a curable resin composition comprising a carboxyl group-containing resin, a photopolymerization initiator, and barium sulfate surfaced with a dispersing agent having an acidic group and/or a dispersing agent having at least any of a block copolymer, a grafted polymer, and a star polymer structure. By such a constitution, it is particularly possible to improve developability of through holes and reduce development residue and it becomes possible to obtain good pattern accuracy, heat resistance, and hardness in a cured product thereof.

In one embodiment of the present invention, it is preferred that a carboxyl group-containing resin has at least one or more ethylenic unsaturated groups in the molecule. By such a constitution, photocurability is increased and it is possible to improve sensitivity.

According to another embodiment of the present invention, provided is a dry film with a dry coating film obtainable by applying the above-mentioned curable resin composition to a carrier film, followed by drying. By the use of such a dry film, it is possible to easily form a dry coating film without applying a curable resin composition to a substrate.

Further, according to one embodiment of the present invention, provided is a cured product obtainable by photocuring, by application of active energy rays, a dry coating film formed on a substrate by applying the above-mentioned curable resin composition to the substrate and then drying it or by laminating a dry film obtained by applying the curable resin composition to a film and drying it. By the use of a cured product obtainable in such a way, it is possible to obtain good pattern accuracy and good coating film properties such as hardness, heat resistance, and insulating property.

Further, according to one embodiment of the present invention, provided is a printed wiring board having a pattern of a cured product obtainable by photocuring, by application of active energy rays, a dry coating film formed on a substrate by applying the above-mentioned curable resin composition to the substrate and then drying it or by laminating a dry film obtained by applying the curable resin composition to a film and drying it. By the use of a printed wiring board obtainable in such a way, it is possible to obtain good pattern accuracy and good resistance to electroless gold plating and electrically insulating property.

### Advantageous Effects of Invention

According to one embodiment of the present invention, it is possible to improve the developability of through holes and suppress generation of development residue in a curable resin composition and it becomes possible to obtain satisfactory heat resistance and hardness in its cured product.

### DESCRIPTION OF EMBODIMENTS

The curable resin composition of this embodiment is characterized by including a carboxyl group-containing resin, a photopolymerization initiator, and barium sulfate surfaced beforehand with a dispersing agent having an acidic group and/or a dispersing agent having at least any of a block copolymer, a grafted polymer, and a star polymer structure.

The present inventors studied earnestly the cause of the increase of development residue in through holes of a printed wiring board in a case where barium sulfate suitable for improving various properties such as heat resistance is contained as an inorganic filler. As a result, they found that barium sulfate bonds to metal such as copper constituting through holes to become easy to remain in the through holes and that development-assisting groups such as acidic functional groups and various surface treating agents having been applied to the surface of barium sulfate (particles) have influence.

Then, as a result of further studies, they found that pretreatment of barium sulfate with a dispersing agent having an acidic group or a dispersing agent having any of a block copolymer, a grafted polymer, and a star polymer structure for adsorption of the dispersing agents onto the surface of the barium sulfate (particles) is effective.

That is, the permeability of an alkali solution is improved by the influence of an acidic group, or the linkage between metal and barium sulfate is relaxed due to the steric hindrance of a dispersing agent by covering therewith the surface of barium sulfate (particles) that easily bonds to metal, and thereby barium sulfate becomes easier to be removed from the inside of through holes. Moreover, it becomes possible to suppress the extension of development treatment time and, thus, it is possible to avoid excess damage to the surface of a coating film of a curable resin composition and to a pattern cross section. Accordingly, in printed wiring boards using a cured product of the composition, it is possible to improve properties particularly liable to be influenced by surface conditions and the shape of a cross section, such as, electroless gold plating and electrically insulating property.

Hereafter, the respective constituents of the curable resin composition of this embodiment are explained in detail.

The carboxyl group-containing resin to be used for the curable resin composition of this embodiment is a component to be added for imparting alkali developability. It maybe any one that has a carboxyl group in its molecule and various known carboxyl group-containing resins can be used. In particular, from the viewpoint of photocurability or development resistance, a carboxyl group-containing photosensitive resin having an ethylenically unsaturated double bond in its molecule is preferred. The unsaturated double bond is preferably one derived from acrylic acid, methacrylic acid, or derivatives thereof.

As such a carboxyl group-containing resin, compounds like those listed below (both oligomers and polymers are useful) are preferred.

(1) Carboxyl group-containing resins obtainable by copolymerization of unsaturated carboxylic acids, such as (meth)acrylic acid, with unsaturated group-containing compounds, such as styrene, alpha-methylstyrene, lower alkyl (meth)acrylates, and isobutylene.

(2) Carboxyl group-containing urethane resins obtainable by polyaddition reaction of diisocyanates, such as aliphatic diisocyanates, branched aliphatic diisocyanates, alicyclic diisocyanates, and aromatic diisocyanates with carboxyl group-containing dialcohol compounds, such as dimethylol propionic acid and dimethylol butanoic acid, and also with diol compounds, such as polycarbonate-type polyols, polyether-type polyols, polyester-type polyols, polyolefin-type polyols, acrylic polyols, and bisphenol A-based alkylene oxide adduct diols, and compounds having a phenolic hydroxyl group and an alcoholic hydroxyl group.

(3) Photosensitive urethane resins containing carboxyl group obtainable by polyaddition reaction of diisocyanates with (meth)acrylates or their partially acid anhydride-modified products of bifunctional epoxy resins, such as bisphenol A type epoxy resins, hydrogenated bisphenol A type epoxy resins, bisphenol F type epoxy resins, bisphenol S type epoxy resins, bixylenol type epoxy resins, and biphenol type epoxy resins, carboxyl group-containing dialcohol compounds, and also with diol compounds.

(4) Photosensitive carboxyl group-containing urethane resins resulting from terminal (meth)acrylation performed by adding a compound having one hydroxyl group and one or more (meth)acryl groups in the molecule, such as hydroxyalkyl (meth)acrylates, during the synthesis of the above-described resin (2) or (3).

(5) Photosensitive carboxyl group-containing urethane resins resulting from terminal (meth)acrylation performed by adding a compound, having one isocyanate group and one or more (meth)acryl groups in the molecule, such as an equimolar reaction product of isophorone diisocyanate with pentaerythritol triacrylate, during the synthesis of the above-described resin (2) or (3).

(6) Photosensitive carboxyl group-containing resins prepared by reacting (meth)acrylic acid to a polyfunctional (solid) epoxy resin with two or more functionalities like that described below, thereby adding a dibasic acid anhydride to a hydroxyl group that exists in a side chain of the epoxy resin.

(7) Photosensitive carboxyl group-containing resins prepared by reacting (meth)acrylic acid to a polyfunctional epoxy resin prepared by further epoxydizing a hydroxyl group of a bifunctional (solid) epoxy resin like that described below with epichlorohydrin, and thereafter adding a dibasic acid anhydride to a resulting hydroxyl group.

(8) Carboxyl group-containing photosensitive resins prepared by adding a cyclic ether such as ethylene oxide and a cyclic carbonate such as propylene carbonate to a polyfunctional phenol compound such as novolac, partially esterifying some of the resulting hydroxyl groups with (meth)acrylic acid, and then reacting a polybasic acid anhydride to the remaining hydroxyl groups.

(9) Photosensitive carboxyl group-containing resins prepared by adding a compound having one epoxy group and one or more (meth)acryl groups in the molecule to the resins of the above-described (1) to (8).

The (meth)acrylate as used herein is a term that collectively encompasses acrylate, methacrylate, and their mixture, and this is also applied to other similar expressions used hereafter.

In the case of using a carboxyl group-containing resin having no ethylenically unsaturated double bonds, it is necessary to use the below-described photosensitive monomer having two or more ethylenic unsaturated groups in its molecule together in order to obtain photocurability.

Such a carboxyl group-containing resin makes it possible to perform development by using a dilute aqueous alkali solution because it has many free carboxyl groups on the side chains of its backbone polymer.

The acid value of a carboxyl group-containing resin is preferably from 10 to 200 mg KOH/g. When the acid value of a carboxyl group-containing resin is less than 30 mg KOH/g, it becomes difficult to perform alkali development. In contrast, when the acid value exceeds 200 mg KOH/g, lines become thinner than needed and, in some cases, dissolution and peeling off are caused by a developing solution without making a distinction between an exposed portion and an unexposed portion, so that it becomes difficult to perform normal formation of a pattern. It is preferably from 30 to 200 mg KOH/g, more preferably from 45 to 120 mg KOH/g.

The weight average molecular weight of a carboxyl group-containing resin, which may vary according to a resin skeleton, is generally preferred to be from 2,000 to 150,000. When the weight average molecular weight is less than 2,000, tack-free performance may be inferior and the moisture resistance of a coating film after exposure to light may be poor, so that film loss may occur during development and resolution may be greatly inferior. In contrast, when the weight average molecular weight exceeds 150,000, developability may become remarkably bad and storage stability may be inferior. It is more preferably from 5,000 to 100,000.

The blended amount of such a carboxyl group-containing resin is preferably 20 to 80% by mass in the composition. When the loading of the carboxyl group-containing resin is less than 20% by mass, then film strength will deteriorate. In contrast, when it exceeds 80% by mass, the viscosity of the composition becomes high, so that coating property and the like will deteriorate. It is more preferably from 30 to 60% by mass.

Such carboxyl group-containing resins may be used singly or two or more of them may be used in combination.

The photopolymerization initiator to be used for the curable resin composition of this embodiment generates a radical upon application of active energy rays and it is added for promoting a crosslinking reaction of the carboxyl group-containing resin. As the photopolymerization initiator, it is preferred to use at least one photopolymerization initiator selected from the group consisting of oxime ester photopolymerization initiators having a group represented by the following formula (I), alpha-aminoacetophenone photopolymerization initiators having a group represented by the following formula (II), and acylphosphine oxide photopolymerization initiators having a group represented by the following formula (III).

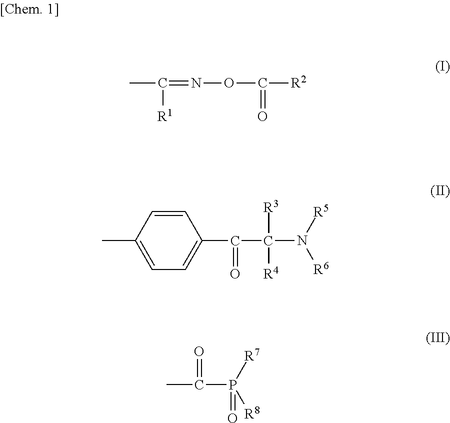

wherein R1 represents a hydrogen atoms, a phenyl group (this may be substituted with an alkyl group having 1 to 6 carbon atoms, a phenyl group, or a halogen atom), an alkyl group having 1 to 20 carbon atoms (this may be substituted with one or more hydroxyl groups and may have one or more oxygen atoms in the middle of the alkyl chain), a cycloalkyl group having from 5 to 8 carbon atoms, an alkanoyl group having 2 to 20 carbon atoms, or a benzoyl group (this may be substituted with an alkyl group having 1 to 6 carbon atoms or a phenyl group); R2 represents a phenyl group (this may be substituted with an alkyl group having 1 to 6 carbon atoms, a phenyl group, or a halogen atom), an alkyl group having 1 to 20 carbon atoms (this may be substituted with one or more hydroxyl groups and may have one or more oxygen atoms in the middle of the alkyl chain), a cycloalkyl group having from 5 to 8 carbon atoms, an alkanoyl group having 2 to 20 carbon atoms, or a benzoyl group (this may be substituted with an alkyl group having 1 to 6 carbon atoms or a phenyl group); R3 and R4 each independently represent a cyclic alkyl ether group which represented an alkyl group having 1 to 12 carbon atoms or an arylalkyl group; R5 and R6 each independently represent a hydrogen atom, an alkyl group having 1 to 6 carbon atoms, or a cyclic alkyl ether group in which the two are combined; R7 and R8 represent independently a linear or branched alkyl group having to 10 carbon atoms, a cyclohexyl group, a cyclopentyl group, an aryl group or an aryl group substituted with a halogen atom, an alkyl group, or an alkoxy group; where one of R7 and R8 may represent a group R—C(═O)— (R is a hydrocarbon group having 1 to 20 carbon atoms).

Examples of the oxime ester photopolymerization initiator having a group represented by formula (I) preferably include
2-(acetyloxyiminomethyl)thioxanthen-9-one represented by the following formula (IV), a compound represented by following formula (V), and a compound represented by the following formula (VI),

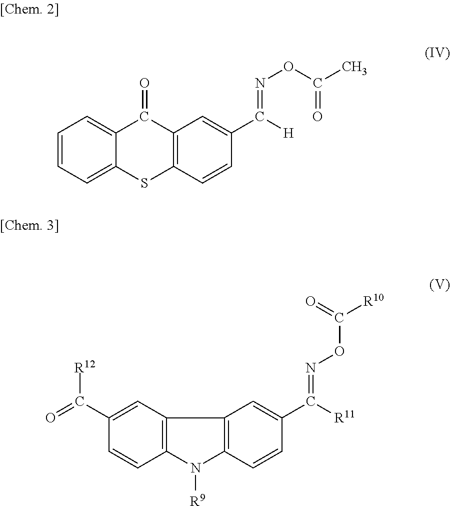

wherein R9 represents a hydrogen atom, a halogen atom, an alkyl group having 1 to 12 carbon atoms, a cyclopentyl group, a cyclohexyl group, a phenyl group, a benzyl group, a benzoyl group, an alkanoyl group having 2 to 12 carbon atoms, and an alkoxycarbonyl group having 2 to 12 carbon atoms (when the number of the carbon atoms of the alkyl group constituting the alkoxyl group is two or more, the alkyl group may be substituted with one or more hydroxyl groups and may have one or more oxygen atoms in the middle of the alkyl chain), or a phenoxycarbonyl group; R10 and R12 each independently represent a phenyl group (this may be substituted with an alkyl group having 1 to 6 carbon atoms, a phenyl group, or a halogen atom), an alkyl group having 1 to 20 carbon atoms (this may be substituted with one or more hydroxyl groups and may have one or more oxygen atoms within the alkyl chain), a cycloalkyl group having from 5 to 8 carbon atoms, an alkanoyl group having 2 to 20 carbon atoms, or a benzoyl group (this may be substituted with an alkyl group having 1 to 6 carbon atoms or a phenyl group); R11 represents a hydrogen atoms, a phenyl group (this may be substituted with an alkyl group having 1 to 6 carbon atoms, a phenyl group, or a halogen atom), an alkyl group having 1 to 20 carbon atoms (this may be substituted with one or more hydroxyl groups and may have one or more oxygen atoms in the middle of the alkyl chain), a cycloalkyl group having from 5 to 8 carbon atoms, an alkanoyl group having 2 to 20 carbon atoms, or a benzoyl group (this may be substituted with an alkyl group having 1 to 6 carbon atoms or a phenyl group);

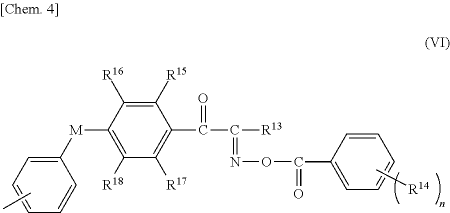

wherein R13 and R14 each independently represent an alkyl group having 1 to 12 carbon atoms; R15, R16, R17, and R18 each independently represent a hydrogen atom or an alkyl group having 1 to 6 carbon atoms; M represents O, S, or NH; and n represents an integer of from 0 to 5.

Among oxime ester photopolymerization initiators,
2-(acetyloxyiminomethyl)thioxanthen-9-one represented by formula (IV) and the compound represented by formula (V) are more preferred. Exemplary commercial products include CGI-325, Irgacure (registered trademark) OXE01, and Irgacure OXE02, produced by BASF Japan. Such oxime ester photopolymerization initiators may be used singly or two or more of them may be used in combination.

Examples of the alpha-aminoacetophenone photopolymerization initiator having a group represented by formula (II) include
2-methyl-1-[4-(methylthio)phenyl]-2-morpholinopropanone-1,
2-benzyl-2-dimethylamino-l-(4-morpholinophenyl)-butan-1-one,
2-(dimethylamino)-2-[(4-methylphenyl)methyl]-1-[4-(4-morpholinyl)phenyl]-1-butanone, and
N,N-dimethylaminoacetophenone. Exemplary commercial products include Irgacure 907, Irgacure 369, and Irgacure 379, produced by BASF Japan.

Examples of the acylphosphine oxide photopolymerization initiator having a group represented by formula (III) include
2,4,6-trimethylbenzoyldiphenylphosphine oxide,
bis(2,4,6-trimethylbenzoyl)phenylphosphine oxide, and
bis(2,6-dimethoxybenzoyl)-2,4,4-trimethylpentylphosphine oxide. Exemplary commercial products include Lucirin TPO produced by BASF and Irgacure 819 produced by BASF Japan.

The blended amount of such a photopolymerization initiator is preferably from 0.01 to 30 parts by mass to 100 parts by mass of the carboxyl group-containing resin. When the blended amount of the photopolymerization initiator is less than 0.01 parts by mass, photocurability on copper will be insufficient, so that a coating film will peel off and coating film properties such as chemical resistance will deteriorate. In contrast, when it exceeds 30 parts by mass, light absorption by the photopolymerization initiator on the surface of a coating film becomes intense, so that deep curability tends to deteriorate. It is more preferably from 0.5 to 15 parts by mass.

In the case of the oxime ester photopolymerization initiator having a group represented by formula (I), its blended amount is preferably from 0.01 to 20 parts by mass to 100 parts by mass of the carboxyl group-containing resin. It is more preferably from 0.01 to 5 parts by mass.

In addition, examples of photopolymerization initiators, photo-coinitiators, and sensitizing agents which can be used suitably for the curable resin composition of this embodiment include benzoin compounds, acetophenone compounds, anthraquinone compounds, thioxanthone compounds, ketal compounds, benzophenone compounds, xanthone compounds, and tertiary amine compounds.

Examples of the benzoin compounds include benzoin, benzoin methyl ether, benzoin ethyl ether, and benzoin isopropyl ether.

Examples of the acetophenone compounds include acetophenone, 2,2-dimethoxy-2-phenylacetophenone, 2,2-diethoxy-2-phenylacetophenone, and 1,1-dichloroacetophenone.

Examples of the anthraquinone compounds include 2-methylanthraquinone, 2-ethylanthraquinone, 2-tert-butylanthraquinone, and 1-chloroanthraquinone.

Examples of the thioxanthone compounds include 2,4-dimethylthioxanthone, 2,4-diethylthioxanthone, 2-chlorothioxanthone, and 2,4-diisopropylthioxanthone.

Examples of the ketal compounds include acetophenone dimethyl ketal and benzyl dimethyl ketal.

Examples of the benzophenone compounds include benzophenone, 4-benzoyldiphenyl sulfide, 4-benzoyl-4′-methyldiphenyl sulfide, 4-benzoyl-4′-ethyldiphenyl sulfide, and 4-benzoyl-4′-propyldiphenyl sulfide.

Examples of the tertiary amine compounds include ethanolamine compounds, compounds having a dialkylaminobenzene structure, for example, dialkylaminobenzophenones such as 4,4′-dimethylaminobenzophenone (NISSOCURE MABP produced by Nippon Soda Co., Ltd.) and 4,4′-diethylaminobenzophenone (EAB produced by Hodogaya Chemical Co., Ltd.); dialkylamino group-containing coumarin compounds such as 7-(diethylamino)-4-methyl-2H-1-benzopyran-2-one (7-(diethylamino)-4-methylcoumarin); and dialkylaminobenzoates such as ethyl 4-dimethylaminobenzoate (KAYACURE (registered trademark) EPA, produced by Nippon Kayaku Co., Ltd.), ethyl 2-dimethylaminobenzoate (Quantacure DMB produced by International Bio-synthetic), (n-butoxy)ethyl 4-dimethylaminobenzoate (Quantacure BEA produced by International Bio-synthetic), isoamylethyl p-dimethylaminobenzoate (KAYACURE DMBI produced by Nippon Kayaku Co., Ltd.), and 2-ethylhexyl 4-dimethylaminobenzoate (Esolol 507 produced by Van Dyk).

In particular, compounds having a dialkylaminobenzene structure are preferred; especially, dialkylaminobenzophenone compounds and dialkylamino group-containing coumarin compounds has a maximal absorption wavelength ranging from 350 to 410 nm are preferred. Among dialkylaminobenzophenone compounds, 4,4′-diethylaminobenzophenone is preferred because of it low toxicity. Dialkylamino group-containing coumarin compounds having a maximal absorption wavelength of from 350 to 410 mm have a maximal absorption wavelength within the ultraviolet light region, so that they are little colored and therefore they make it possible to afford colorless transparent photosensitive compositions as well as, by using a color pigment, colored solder resist films showing the intrinsic color of the color pigment. In particular,
7-(diethylamino)-4-methyl-2H-1-benzopyran-2-one is preferred because it exhibits a superior sensitization effect to a laser beam having a wavelength of from 400 to 410 nm.

Among these compounds, thioxanthone compounds and tertiary amine compounds are preferred. In particular, inclusion of a thioxanthone compound is preferred from the viewpoint of deep curability.

The blended amount of such a thioxanthone compound is preferably 20 parts by mass or less to 100 parts by mass of the carboxyl group-containing resin. When the blended amount of the thioxanthone compound is too high, the thick film curability will deteriorate to result in the increase of the production cost. It is more preferably 10 parts by mass or less.

The blended amount of the tertiary amine compound is preferably from 0.1 to 20 parts by mass to 100 parts by mass of the carboxyl group-containing resin. When the blended amount of the tertiary amine compound is less than 0.1 parts by mass, the sensitization effect tends not to be achieved sufficiently. When the blended amount exceeds 20 parts by mass, the tertiary amine compound violently absorbs light on the surface of the dry solder resist coating film, so that deep curability may deteriorate. It is more preferably from 0.1 to 10 parts by mass.

Such photopolymerization initiators, Photopolymerization initiator aids, and sensitizers can be used singly or as a mixture of two or more kinds thereof.

The total amount of the photopolymerization initiator, photopolymerization initiator aid, and sensitizer is preferably 35 parts by mass or less to 100 parts by mass of the carboxyl group-containing resin. When it exceeds 35 parts by mass, deep curability may deteriorate due to optical absorption caused by these agents.

The barium sulfate to be used for the curable resin composition of this embodiment is added for the purposes of suppressing the cure shrinkage of a film and improving properties such as adhesion property, hardness, and heat resistance.

As such barium sulfate, known barium sulfate can be used; both a ground product of naturally occurring barite mineral called barite and precipitated barium sulfate prepared by chemical synthesis can be used. Among these, precipitated barium sulfate is preferred because the size of its particles can be controlled according to the conditions to be used during its synthesis.

Such barium sulfate needs to be surface-treated with a dispersing agent having an acidic group and/or a dispersing agent having at least any of a block copolymer, a grafted polymer and a star polymer structure. By the surface treatment of barium sulfate (particles) with such a dispersing agent, barium sulfate (particles) is dispersed in a curable resin composition uniformly, thereby improving developability, especially through hole developability.

The dispersing agent having an acidic group is adsorbed onto the surface of barium sulfate (particles) and performs to help barium sulfate to be developed and removed from a base surface and from a through hole portion by the attack of an aqueous alkali solution to the acidic group in the dispersing agent.

As such a dispersing agent having an acidic group, preferred is one containing a copolymer containing an acidic group. Basic skeletons thereof include skeletons composed of an ester chain, a vinyl chain, an acrylic chain, an ether chain, a urethane chain, etc. Some of the hydrogen atoms in the molecules may be substituted by halogen atoms. Among these, acrylic resins, urethane resins, polyester resins, and alkyd resins are preferred and, particularly, acrylic resins, urethane resins, and polyester resins are preferred.

Although acidic groups may be arranged completely at random in molecules of a resin, preferred is a resin in which acidic groups are arranged at terminals of molecules by a block or graft structure. This is because the arrangement of acidic groups at terminals increases adsorption performance to barium sulfate (particles), thereby improving the developability of through holes.

Examples of such an acidic group include a carboxyl group, a sulfone group, and a phosphoric acid group and, among these, a phosphoric acid group and a carboxyl group are preferred.

The acid value of the dispersing agent having an acidic group is preferably from 5 to 200 mg KOH/g. When the acid value is less than 5 mg KOH/g, adsorbing force to barium sulfate (particles) becomes short and developability of through holes cannot be increased sufficiently. In contrast, when it exceeds 200 mg KOH/g, deterioration of characteristics, such as heat resistance of gold plating resistance, of a resin composition may be caused. It is more preferably from 30 to 160 mg KOH/g.

A dispersing agent having a block copolymer, a grafted polymer, or a star polymer structure is adsorbed onto the surface of barium sulfate (particles) at a high ratio to cover the surface of the barium sulfate (particles) with a polymer, thereby inhibiting a reaction with metal forming a circuit, such as copper on a base, due to its steric hindrance. As a result, linkage between the barium sulfate (particles) and the base is inhibited from becoming strong, so that it is relaxed and developability of through holes is improved. Linear random copolymers cannot sufficiently inhibit reaction between barium sulfate and a base because they are low in adsorption ratio to the surface of barium sulfate (particles) and do not have sufficient steric hindrance.

Among these, examples of the block copolymer and the grafted polymer include those composed of an ester chain, a vinyl chain, an acrylic chain, an ether chain, a urethane chain, etc. as their basic skeletons. Some of the hydrogen atoms in the molecules may be substituted by halogen atoms. Among these, acrylic resins, urethane resins, polyester resins, and alkyd resins are preferred and, particularly, acrylic resins, urethane resins, and polyester resins are preferred.

Such block copolymers and grafted polymers are preferably those prepared by controlled synthesis using living polymerization; they will provide enhanced adsorption performance to barium sulfate (particles) and therefore can improve developability of through holes.

The star polymer structure is a branched polymer structure having linear side chains spreading radially from the central core, wherein the core may be a single atom or a molecular group or a semi-spherical structural body. Preferably, the linear side chains of such a star polymer are composed of three or more side changes differing in structure and the respective side chains differ in polarity.

The molecular weight of such a dispersing agent having a block copolymer, a grafted polymer, or a star polymer structure is preferably from 1,000 to 300,000. When it is less than 1000, the dispersing agent cannot sufficiently inhibit reaction between barium sulfate and a base metal because the dispersing agent is low in adsorption ratio to the surface of barium sulfate (particles) and does not have sufficient steric hindrance. In contrast, when it exceeds 300,000, the resin itself will agglomerate so greatly that the effect of dispersing barium sulfate particles will be lost. It is more preferably from 3000 to 100,000.

The dispersing agent is not necessary to have an acidic group and any of block copolymerization, graft polymerization, or a star polymer structure simultaneously. That is, one that has an acidic group but does not have block copolymerization, graft polymerization, or a star polymer structure and one that has block copolymerization, graft polymerization, or a star polymer structure but does not have an acidic group both work well because their working mechanisms are different. It is noted that when such a dispersing agent having block copolymerization, grafted polymerization, or a star polymer structure also has an acidic group, the permeability of a dilute aqueous alkali solution is improved, so that developability of through holes can be improved more.

The case where the dispersing agent of the present invention contains an amino group, amide, or an ammonium group is more preferred because these groups will interact with the acidic groups of the carboxyl group-containing resin to relax strong linkage between barium sulfate and the surface of a substrate.

Examples of such a dispersing agent include, but are not limited to, Disperbyk, (Registered trademark)-102, -106, -110, -111, 140, -142, -145, -180, -2001, -2020, -2025, -2070, -2090, -2164, and -P105 (all are produced by BYK-Chemie Japan), SOLSPERSE(registered trademark) 32000, 36000, 41000, and 76500 (all are produced by The Lubrizol Corporation), and FLOWLEN G700, FLOWLEN G900, and FLOWLEN KDG-6000 (produced by Kyoeisha Chemical Co., Ltd.).

Such a dispersing agent is not necessary to be adsorbed wholly to the surface of barium sulfate. That is, it may be adsorbed to the surface of another filler, which will be described later or may contribute to dispersion of a coloring agent or the like, which also will be described later. The content of the dispersing agent in a curable resin composition, the suitable range of which may vary depending upon the structure and molecular weight of the dispersing agent to be used, is preferably from 0.05% by mass to 50% by mass relative to barium sulfate. When the content is less than 0.05% by mass, deterioration in developability of through holes will be caused and the viscosity of the curable resin composition will increase, causing decrease in dispersion degree. In contrast, when it is more than 50% by mass, adhesion property, heat resistance, and resistance to gold plating will deteriorate. It is more preferably from 0.1% by mass to 30% by mass.

Such dispersing agents can be used singly or two or more of them can be used in combination unless they mutually impair their effects. When two or more dispersing agents are used in combination, it is preferred that the total amount does not exceed the above-mentioned range.

As far as the effect of the dispersing agent of this embodiment is not disturbed, known dispersing agents other than the above-described dispersing agent may be used singly or two or more of them may be used in combination for dispersing the coloring agent described later and the like. In this case, it is preferred that the sum total of the amounts of the dispersing agents does not exceed above-mentioned range. Such dispersing agents may be used in any form of solution, slurry, paste, and powder. Such barium sulfates may be used singly or two or more of them may be used in combination.

The blended amount of such barium sulfate is preferably from 1 to 500 parts by mass to 100 parts by mass of the carboxyl group-containing resin. When the blended amount of barium sulfate is less than 1 part by mass, deterioration in adhesion property, heat resistance and so on will occur. In contrast, when it exceeds 500 parts by mass, the viscosity of a photosensitive resin composition will become high, so that the printability thereof will deteriorate and a cured product of the composition will become brittle. It is more preferably from 10 to 300 parts by mass.

In the curable resin composition of this embodiment, fillers (extender pigments) other than barium sulfate may be used singly or two or more of them may be used in combination according to need in order to increase physical strength or the like of a coating film of the composition. As such fillers, known inorganic or organic fillers can be used and, especially, spherical silica and talc are preferred. Moreover, in order to attain white appearance or flame retardancy, metal oxides such as titanium oxide and metal hydroxides such as aluminum hydroxide can be used.

Moreover, NANOCRYL (registered trademark) XP 0396, XP 0596, XP 0733, XP 0746, XP 0765, XP 0768, XP 0953, XP 0954, and XP 1045 (all are grade names of products) produced by Hanse-Chemie, NANOPDX (registered trademark) XP 0516, XP 0525, and XP 0314 (all are grade names of products) produced by Hanse-Chemie, in which nanosilica is dispersed in a compound having one or more ethylenically unsaturated groups or a polyfunctional epoxy resin, may also be used.

The blended amount of such a filler, totaled with barium sulfate, is preferably 75% by mass or less of the overall amount of the curable resin composition. When the blended amount of the filler exceeds 75% by mass of the entire amount, the viscosity of the insulating composition will become high and the coatability, printability, and moldability of the composition will deteriorate and a cured product of the composition will become brittle. It is more preferably from 0.1 to 60% by mass.

For the curable resin composition of this embodiment, a thermosetting resin can be used in order to impart heat resistance. As the thermally curable component used for this embodiment, known thermosetting resins can be used such as amine resins, e.g., melamine resin and benzoguanamine resin, block isocyanate compounds, cyclocarbonate compounds, polyfunctional epoxy compounds, polyfunctional oxetane compounds, episulfide resins, melamine derivatives, bismaleimide, oxazine compounds, oxazoline compounds, and carbodiimide resins. Particularly preferred is a thermally curable component having two or more cyclic ether groups and/or cyclic thioether groups (hereinafter referred to as cyclic (thio)ether groups) in the molecule thereof.

Such a thermally curable component having two or more cyclic (thio)ether groups in a molecule thereof is a compound having either one of a 3-, 4-, 5-membered cyclic ether group or cyclic thioether group or two or more groups of two kinds in the molecule thereof; examples thereof include compounds at least having two or more epoxy groups in the molecule thereof, i.e., polyfunctional epoxy compounds, compounds at least having two or more oxetanyl groups in the molecule thereof, i.e., polyfunctional oxetane compounds, and compounds at least having two or more thioether groups in the molecule thereof, i.e., episulfide resins.

Examples of the polyfunctional epoxy compound include, but not limited to, bisphenol A-type epoxy resins such as EPICOAT jER(registered trademark) 828, jER 834, jER 1001, and jER 1004 (all are produced by Mitsubishi Chemical Corporation), EPICLON (registered trademark) 840, EPICLON 850, EPICLON 1050, and EPICLON 2055 (all are produced by DIC Corporation), EPOTOHTO (registered trademark) YD-011, YD-013, YD-127, and YD-128 (all are produced by NSCC Epoxy Manufacturing Co., Ltd.), D.E.R. 317, D.E.R. 331, D.E.R. 661, and D.E.R. 664 (all are produced by the Dow Chemical Co.), ARALDITE 6071, ARALDITE 6084, ARALDITE GY250, and ARALDITE GY260 (all are produced by BASF Japan), SUMI-EPDXY ESA-011, ESA-014, ELA-115, and ELA-128 (all are produced by Sumitomo Chemical Co., Ltd.), and A.E.R. 330, A.E.R. 331, A.E.R. 661, and A.E.R. 664 (all are produced by Asahi Kasei Corporation); brominated epoxy resins such as jERYL903 (produced by Mitsubishi Chemical Corporation), EPICLON 152 and EPICLON 165 (both are produced by DIC Corporation), EPOTOHTO YDB-400 and YDB-500 (both are produced by NSCC Epoxy Manufacturing Co., Ltd.), D.E.R. 542 (produced by the Dow Chemical Co.), ARALDITE 8011 (produced by BASF Japan), SUMI-EPDXY ESB-400 and ESB-700 (both are produced by Sumitomo Chemical Co., Ltd.), and A.E.R.711 and A.E.R.714 (both are produced by Asahi Kasei Corporation); novolac-type epoxy resins such as jER152 and jER154 (both are produced by Mitsubishi Chemical Corporation), D.E.N. 431 and D.E.N.438 (both are produced by the Dow Chemical Co.), EPICLON N-730, EPICLON N-770, and EPICLON N-865 (all are produced by DIC Corporation), EPOTOHTO YDCN-701 and YDCN-704 (both are produced by NSCC Epoxy Manufacturing Co., Ltd.), ARALDITE ECN1235, ARALDITE ECN1273, ARALDITE ECN1299, and ARALDITE XPY307 (all are produced by BASF Japan), EPPN-201, EOCN (registered trademark)-1025, EOCN-1020, EOCN-104S, and RE-306 (all are produced by Nippon Kayaku Co., Ltd.), SUMI-EPDXY ESCN-195X and ESCN-220 (both are produced by Sumitomo Chemical Co., Ltd.), and A.E.R. ECN-235 and ECN-299 (both are produced by Asahi Kasei Corporation); bisphenol F-type epoxy resins such as EPICLON 830 (produced by DIC Corporation), jER807 (produced by Mitsubishi Chemical Corporation), EPOTOHTO YDF-170, YDF-175, and YDF-2004 (all are produced by NSCC Epoxy Manufacturing Co., Ltd.), and ARALDITE XPY306 (produced by BASF Japan); hydrogenated bisphenol A-type epoxy resins such as EPOTOHTO ST-2004, ST-2007, and ST-3000 (all are produced by NSCC Epoxy Manufacturing Co., Ltd.); glycidyl amine-type epoxy resins such as jER604 (produced by Mitsubishi Chemical Corporation), EPOTOHTO YH-434 (produced by NSCC Epoxy Manufacturing Co., Ltd.), ARALDITE MY720 (produced by BASF Japan), and SUMI-EPDXY ELM-120 (produced by Sumitomo Chemical Co., Ltd.); hydantoin-type epoxy resins such as ARALDITE CY-350 (produced by BASF Japan); alicyclic epoxy resins such as CELLOXIDE (registered trademark) 2021 (produced by Daicel Chemical Industries, Ltd.), and ARALDITE CY175 and CY179 (both are produced by BASF Japan); trihydroxyphenylmethane-type epoxy resins such as YL-933 (produced by Mitsubishi Chemical Corporation), and T E.N., EPPN(registered trademark)-501, and EPPN-502 (all are produced by Nippon Kayaku Co., Ltd.); bixylenol-type or biphenol-type epoxy resins and mixtures thereof such as YL-6056, YX-4000, and YL-6121 (all are produced by Mitsubishi Chemical Corporation); bisphenol S-type epoxy resins such as EBPS-200 (produced by Nippon Kayaku Co., Ltd.), EPX-30 (produced by Adeka Corporation), and EXA-1514 (produced by DIC Corporation); bisphenol A novolac-type epoxy resins such as jER 157S (produced by Mitsubishi Chemical Corporation); tetraphenylolethane-type epoxy resins such as jERYL-931 (produced by Mitsubishi Chemical Corporation), and ARALDITE 163 (produced by BASF Japan); heterocyclic epoxy resins such as ARALDITE PT810 (produced by BASF Japan), and TEPIC (produced by Nissan Chemical Industries, Ltd.); diglycidyl phthalate resins such as BLEMMER (registered trademark) DGT (produced by NOF Corporation); tetraglycidylxylenoylethane resins such as ZX-1063 (produced by NSCC Epoxy Manufacturing Co., Ltd.); naphthalene group-containing epoxy resins such as ESN-190 and ESN-360 (both are produced by Nippon Steel Chemical Co., Ltd.), and HP-4032, EXA-4750, and EXA-4700 (all are produced by DI C Corporation); epoxy resins having a dicyclopentadiene skeleton such as HP-7200 and HP-7200H (produced by DIC Corporation); glycidyl methacrylate copolymer-based epoxy resins such as CP-50S and CP-50M (both are produced by NOF Corporation); cyclohexylmaleimide-glycidyl methacrylate copolymer epoxy resins; and epoxy-modified polybutadiene rubber derivatives (for example, PB-3600 produced by Daicel Chemical Industries, Ltd.) and CTBN-modified epoxy resins (for example, YR-102 and YR-450 produced by NSCC Epoxy Manufacturing Co., Ltd.). Such epoxy resins may be used solely or two or more of them may be used in combination. Among these, novolac-type epoxy resins, heterocyclic epoxy resins, bisphenol A-type epoxy resins, and mixtures thereof are particularly preferred.

Examples of the polyfunctional oxetane compound include polyfunctional oxetanes such as
bis[(3-methyl-3-oxetanylmethoxy)methyl]ether,
bis[(3-ethyl-3-oxetanylmethoxy)methyl]ether,
1,4-bis[(3-methyl-3-oxetanylmethoxy)methyl]benzene,
1,4-bis[(3-ethyl-3-oxetanylmethoxy)methyl]benzene, and
oligomers thereof, (3-methyl-3-oxetanyl)methyl acrylate, (3-ethyl-3-oxetanyl)methyl acrylate, (3-methyl-3-oxetanyl)methyl methacrylate, (3-ethyl-3-oxetanyl)methyl methacrylate, and oligomers or copolymers thereof; and ethers of oxetane alcohol with resins having hydroxyl groups such as novolac resins, poly(p-hydroxystyrene), cardo-type bisphenols, calixarenes, calix resorcin arenes, and silsesquioxane. Other examples include copolymers of oxetane ring-containing unsaturated monomers with alkyl (meth)acrylates.

Examples of the episulfide compound include a bisphenol A-type episulfide resin, YL7000 produced by Mitsubishi Chemical Corporation. Episulfide resins prepared by replacing oxygen atoms of epoxy groups of novolac-type epoxy resins by sulfur atoms by a similar synthesis method may also be used.

The blended amount of the thermally curable component having two or more cyclic (thio)ether groups in the molecule is preferably from 0.6 to 2.5 equivalents per equivalent of the carboxyl groups of the carboxyl group-containing resin. When the blended amount is less than 0.6 equivalents, carboxyl groups remain in a solder resist film, so that its heat resistance, alkali resistance, electrically insulating property, and so on may deteriorate. In contrast, when the blended amount exceeds 2.5 equivalents, low molecular weight cyclic (thio)ether groups will remain in a dry coating film, so that the strength of the coating film and other properties may deteriorate. It is more preferably from 0.8 to 2.0 equivalents.

When a thermally curable component having two or more cyclic (thio)ether groups in the molecule is used, the composition preferably contains a thermosetting catalyst. Examples of such a thermosetting catalyst include imidazole and imidazole derivatives, such as 2-methylimidazole, 2-ethyl imidazole, 2-ethyl-4-methylimidazole, 2-phenylimidazole, 4-phenylimidazole, 1-cyanoethyl-2-phenylimidazole, and 1-(2-cyanoethyl)-2-ethyl-4-methylimidazole; amine compounds, such as dicyandiamide, benzyldimethylamine, 4-(dimethylamino)-N,N-dimethylbenzylamine, 4-methoxy-N,N-dimethylbenzylamine, and 4-methyl-N,N-dimethylbenzylamine, hydrazine compounds, such as adipic acid dihydrazide and sebacic acid dihydrazide, and phosphorus compounds, such as triphenylphosphine; and examples of its commercial products include 2MZ-A, 2MZ-OK, 2PHZ, 2P4BHZ, and 2P4MHZ (all are trade names of imidazole-based compounds) produced by Shikoku Chemicals Corporation, U-CAT (registered trademark) 3503N and U-CAT3502T (both are trade names of dimethylamine block isocyanate compounds) produced by San-Apro Ltd., and DBU, DBN, U-CATSA102, and U-CAT5002(all are trade names of dicyclic amidine compounds and salts thereof). The catalyst is not limited to these and a thermosetting catalyst for epoxy resins or oxetane compounds or a substance which accelerates the reaction between an epoxy group and/or oxetanyl group and a carboxyl group can be used; these catalysts may be used singly or two or more of them may be used in combination.

It is also permitted to use guanamine, acetoguanamine, benzoguanamine, melamine, S-triazine derivatives, such as
2,4-diamino-6-methacryloiloxyethyl-S-triazine,
2-vinyl-2,4-diamino-S-triazine,
2-vinyl-4,6-diamino-S-triazine.isocyanuric acid adducts, and
2,4-diamino-6-methacryloiloxyethyl-S-triazine isocyanuric acid adducts. It is preferred to use such a compound that serves also as a tackifier together with a thermosetting catalyst.

As to the blended amount of such a thermosetting catalyst, an ordinary quantitative proportion is much enough and, for example, it is preferably from 0.1 to 20 parts by mass, more preferably from 0.5 to 15 parts by mass to 100 parts by mass of the carboxyl group-containing resin or the thermally curable component having two or more cyclic (thio) ether groups in the molecule thereof.

In order to produce a color suitable as a solder resist layer of a printed wiring board, a coloring agent maybe blended to the curable resin composition of this embodiment. As the coloring agent, known coloring agents, such as red agents, blue agents, green agents, and yellow agents, can be used and any of pigments, dyes, and colorants are usable. From the viewpoints of reduction of environmental load and influence to the human body, it is preferred that the coloring agent does not contain halogen.

Red coloring agents include monoazo series, disazo series, azo lake series, benzimidazolone series, perylene series, diketopyrrolopyrrole series, condensed azo series, anthraquinone series, and quinacridone series, etc. and specifically include the following coloring agents identified by Color Index (published by The Society of Dyers and Colourists) Numbers.

Monoazo series: Pigment Red 1, 2, 3, 4, 5, 6, 8, and 9, 12, 14, 15, 16, and 17, 21, 22, 23, 31, 32, 112, 114, 146, 147, 151, 170, 184, 187, 188, 193, 210, 245, 253, 258, 266, 267, 268, and 269.

Disazo series: Pigment Red 37, 38, and 41.

Monoazo lake series: Pigment Red 48:1, 48:2, 48:3, 48:4, 49:1, 49:2, 50:1, 52:1, 52:2, 53:1, 53:2, 57:1, 58:4, 63:1, 63:2, 64:1, and 68.

Benzimidazolone series: Pigment Red 171, 175, 176, 185, and 208.

Perylene series: Solvent Red 135, 179, and Pigment Red 123, 149, 166, 178, 179, 190, 194, and 224.

Diketopyrrolopyrrole series: Pigment Red 254, 255, 264, 270, and 272.

Condensed azo series: Pigment Red 220, 144, 166, 214, 220, 221, and 242.

Anthraquinone series: Pigment Red 168, 177, and 216 and Solvent Red 52, 149, 150, and 207.

Quinacridone series: Pigment Red 122, 202, 206, 207, and 209.

Blue coloring agents include phthalocyanine series and anthraquinone series, and there can be used Pigment Blue 15, 15:1, 15:2, 15:3, 15:4, 15:6, 16, 60, etc. as pigment type colorants and Solvent Blue 35, 63, 67, 68, 70, 83, 87, 94, 97, and 122, 136, etc. as dye type colorants. Besides these, metal-substituted or unsubstituted phthalocyanine compounds may also be used.

Likewise, green coloring agents include phthalocyanine series, anthraquinone series, and perylene series and, for example, Pigment Green 7, 36, Solvent Green 3, 5, 20, and 28 may be used. Besides these, metal-substituted or unsubstituted phthalocyanine compounds may also be used.

Yellow coloring agents include monoazo series, disazo series, condensed azo series, benzimidazolone series, isoindolinone series, and anthraquinone series and specifically include the following.

Anthraquinone series: Solvent Yellow 163 and Pigment Yellow 24, 108, 193, 147, 199, and 202.

Isoindolinone series: Pigment Yellow 109, 110, 139, 179, and 185.

Condensed azo series: Pigment Yellow 93, 94, 95, 128, 155, 166, and 180.

Benzimidazolone series: Pigment Yellow 120, 151, 154, 156, 175, and 181.

Monoazo series: Pigment Yellow 1, 2, 3, 4, 5, 6, 9, 10, 12, 61, 62, 62:1, 65, 73, 74, 75, 97, 100, 104, 105, 111, 116, 167, 168, 169, 182, and 183.

Disazo series: Pigment Yellow 12, 13, 14, 16, 17, 55, 63, 81, 83, 87, 126, 127, 152, 170, 172, 174, 176, 188, and 198.

In addition, coloring agents, such as purple one, orange one, brown one, and black one, may be added in order to adjust color tone. Specific examples include Pigment Violet 19, 23, 29, 32, 36, 38, and 42, Solvent Violet 13, 36, Pigment Orange 1, 5, 13, 14, 16, 17, 24, 34, 36, 38, 40, 43, 46, 49, 51, 61, 63, 64, 71, and 73, Pigment Brown 23, 25, and Pigment Black 1, 7.

Although the blend ratio of such coloring agents is not particularly limited, a sufficient ratio is preferably from 0 to 10 parts by mass, particularly preferably from 0.1 to 5 parts by mass to 100 parts by mass of the carboxyl group-containing resin.

For the curable resin composition of this embodiment, a compound having two or more ethylenically unsaturated groups in the molecule thereof can be used for insolubilizing a resin composition in an aqueous alkali solution or aiding such insolubilization through photopolymerization upon the application of active energy rays.

Examples of such compounds include diacrylates of glycol, such as ethylene glycol, methoxytetraethylene glycol, polyethylene glycol, and propylene glycol; polyfunctional acrylates of polyhydric alcohols or ethylene oxide adducts or propylene oxide adducts thereof such as hexanediol, trimethylolpropane, pentaerythritol, dipentaerythritol, and tris-hydroxyethyl isocyanurate; polyfunctional acrylates such as phenoxy acrylate, bisphenol A diacrylate, and ethylene oxide adducts or propylene oxide adducts of these phenols; polyfunctional acrylates of glycidyl ethers such as glycerol diglycidyl ether, glycerol triglycidyl ether, trimethylolpropane triglycidyl ether, and triglycidyl isocyanurate; and melamine acrylate, urethane acrylates and/or methacrylates corresponding to such acrylates.

Other examples include epoxy acrylate resins prepared by reacting a polyfunctional epoxy resin such as a cresol novolac type epoxy resin with acrylic acid, and epoxy urethane acrylate compounds prepared by reacting hydroxy groups of the epoxy acrylate resin with a half urethane compound prepared from a hydroxy acrylate such as pentaerythritol triacrylate and a diisocyanate such as isophorone diisocyanate. These epoxy acrylate-based resins can improve photocurability without deteriorating dryability by finger touch.

The blended amount of such a compound having two or more ethylenically unsaturated groups in the molecule is preferably from 5 to 100 parts by mass to 100 parts by mass of the aforementioned ethylenically unsaturated group-containing carboxyl group-containing resin. When the blended amount is less than 5 parts by mass, photocurability deteriorates and it becomes difficult to form a pattern by alkali development after application of active energy rays. In contrast, when it exceeds 100 parts by mass, solubility in aqueous alkali solutions deteriorates and coating films become brittle. It is more preferably from 1 to 70 parts by mass.

Moreover, the curable resin composition of this embodiment can use an organic solvent for synthesis of a carboxyl group-containing resin or adjustment of the composition or for viscosity control for application to a substrate or a carrier film.

Examples of such an organic solvent include ketones, aromatic hydrocarbons, glycol ethers, glycol ether acetates, esters, alcohols, aliphatic hydrocarbons, and petroleum solvents. More specific examples include ketones such as methyl ethyl ketone and cyclohexanone; aromatic hydrocarbons such as toluene, xylene, and tetramethylbenzene; glycol ethers such as cellosolve, methylcellosolve, butylcellosolve, carbitol, methyl carbitol, butyl carbitol, propylene glycol monomethyl ether, dipropylene glycol monomethyl ether, dipropylene glycol diethyl ether, and triethylene glycol monoethyl ether; esters such as ethyl acetate, butyl acetate, dipropylene glycol methyl ether acetate, propylene glycol methyl ether acetate, propylene glycol ethyl ether acetate, and propylene glycol butyl ether acetate; alcohols such as ethanol, propanol, ethylene glycol, and propylene glycol; aliphatic hydrocarbons such as octane and decane; and petroleum solvents such as petroleum ether, petroleum naphtha, hydrogenated petroleum naphtha, and solvent naphtha. Such organic solvents may be used singly or as a mixture of two or more of them.

The curable resin composition of this embodiment may further contain publicly known additives, such as publicly known thermal polymerization inhibitors such as hydroquinone, hydroquinone monomethyl ether, tert-butylcatechol, pyrogallol, and phenothiazine; publicly known thickening agents such as fine powder silica, organic bentonite, and montmorillonite; defoaming agents and/or leveling agents such as silicone-based agents, fluorine-based agents, and polymer-based agents; and silane coupling agents, antioxidants, and rust inhibitors such as imidazole-based agents, thiazole-based agents, and triazole-based agents.

Such a curable resin composition is prepared, for example, in the following way and is used for the formation of a solder resist layer and so on.

Barium sulfate is surface-treated with a dispersing agent having an acidic group and/or a dispersing agent at least having any of a block copolymer, a grafted polymer and a star polymer structure, thereby making the surface of the barium sulfate (particles) adsorb the dispersing agents, and then mixing it with resins such as a carboxyl group-containing resin and a photopolymerization initiator in a prescribed ratio. The method for treating barium sulfate (particles) with a dispersing agent is not particularly restricted and examples thereof include the following methods.

(1) A method that comprises mixing barium sulfate with a dispersing agent by a known method beforehand, adding and mixing the resulting treatment liquid to a part or the whole of the remaining components, and then dispersing the resultant into resins.

(2) A method that comprises adding barium sulfate and a dispersing agent separately in prescribed ratios to a part or the whole of the components, including resins, other than the barium sulfate and the dispersing agent, and performing treatment in the resins.

(3) A method that comprises adding barium sulfate and a dispersing agent separately to resins, an organic solvent, and so on, and then mixing the resulting treatment liquids in prescribed ratios, thereby performing treatment.

(4) A method that comprises adding a dispersing agent in a prescribed ratio to a dispersion liquid prepared by dispersing barium sulfate in resins and so on, and then performing treatment.

Although any of the methods (1) through (4) may be used, it is necessary to have completed the surface treatment before applying the curable resin composition to a base.

As a mixing method, known methods can be used, and it is not particularly restricted. Either of a method of performing mixing without using a dispersing machine or a method of performing mechanical mixing by using various types of dispersing machine, such as a kneader, a roll, an attritor, and a bead mill, may be used.

Particularly preferred methods include a method that comprises mixing a dispersion liquid prepared by mixing barium sulfate with a solvent and a dispersing agent beforehand and then dispersing it by a dispersing machine such as a bead mill with other curable resin composition or performing roll mill dispersion again according to need, or a method that comprises mixing a dispersion liquid prepared by mixing a part of resin components and barium sulfate with a solvent and a dispersing agent by a dispersing machine such as a bead mill beforehand with other curable resin composition or performing roll mill dispersion according to need.

In adding a coloring agent, it is preferred, from the viewpoint of dispersibility, to add and mix a liquid in which a coloring agent-dispersing agent has been dissolved or finely dispersed to a mixed liquid in which powders including the coloring agent have been dispersed beforehand in water or an organic solvent.

After preparing a curable resin composition in a prescribed composition in the way described above, it is adjusted to have a viscosity suitable for an application method with an organic solvent and then it is applied to a substrate by a certain method, for example, dip coating, flow coating, roll coating, bar coating, screen printing, or curtain coating.

After the formation of a coating film by applying a curable resin composition, evaporative drying is performed, thereby forming a dry coating film. The evaporative drying can be performed, for example, at a temperature of about 60° C. to about 100° C., and there can be used, for example, a hot air circulating drying oven, an IR oven, a hot plate, or a convection oven (a system of flowing hot air in the dryer in the counter directions and bringing the flows into contact with each other or a system of blowing the hot air through a nozzle onto a substrate).

Moreover, it is also possible to form a dry coating film by forming a dry film from the curable resin composition of this embodiment and then laminating it to a substrate.

The dry film is, for example, one having a structure in which a carrier film of polyethylene terephthalate or the like, a dry coating film to be used for a solder resist layer, and a removable cover film to be used according to need are laminated in this order.

The dry coating film is a layer obtainable by applying a curable resin composition to a carrier film or a cover film and then drying it. Such a dry coating film is formed by applying the curable resin composition of this embodiment uniformly in a thickness of from 10 to 150 μm to a carrier film with a blade coater, a lip coater, a comma coater, a film coater, or the like, and then drying it. Moreover, a dry film is formed by further laminating a cover film according to need. At this time, it is also permitted to laminate a carrier film after applying the curable resin composition to the cover film and drying it.

As the carrier film, a thermoplastic film such as a polyester film having a thickness of from 2 to 150 μm is used, for example.

Although a polyethylene film, a polypropylene film, and the like can be used as the cover film, one having an adhesive force to a solder resist layer weaker than the carrier film is preferred.

By using such a dry film, peeling a cover film if used, piling a dry coating film and a substrate together, and laminating them with a laminating machine or the like, the dry coating film is formed on the substrate. The carrier film may be peeled off before or after application of light, which is described later. At this time, examples of the substrate on which such a dry coating film is to be formed include copper-clad laminates of all grades (FR-4, etc.) using materials such as copper-clad laminates for high frequency circuits, etc. using paper phenol, paper epoxy, glass fabric epoxy, glass polyimide, glass fabric/nonwoven fabric epoxy, glass fabric/paper epoxy, synthetic fiber epoxy, fluorine.polyethylene.PPO.cyanate ester, etc., other polyimide films, PET films, glass substrates, ceramic substrates, and wafers.

Further, light is applied by using active energy rays selectively by a contact system (or non-contact system) through a patterned photomask or patterned light is applied directly by using a laser direct aligner.

As the aligner to be used for the application of active energy rays, for example, a direct imaging apparatus such as a laser direct imaging apparatus that draws an image directly by laser by CAD data from a computer, an aligner equipped with a metal halide lamp, an aligner equipped with a mercury short arc lamp, or a direct imaging apparatus using a ultraviolet lamp such as a (ultra)high-pressure mercury lamp can be used. As the direct imaging apparatus, one manufactured by Orbotech Japan Ltd., one manufactured by PENTAX Corporation, and so on can be used, for example.

The wavelength of active energy rays is preferably within a range of from 350 to 410 nm. By adjusting the wavelength to within this range, a radical can be produced efficiently from a photopolymerization initiator. In particular, it is preferred to use a laser beam, and both gas laser and solid laser can be used as far as they have a wavelength within that range. The applied amount of light, which may vary depending upon film thickness and so on, is generally from 5 to 800 mJ/cm² and preferably from 10 to 600 mJ/cm².

By the application of light in such a way, exposed portions (portions irradiated with active energy rays) are cured. Moreover, unexposed portions are developed by a dilute aqueous alkali solution (for example, 0.3 to 3 wt % aqueous sodium carbonate solution), so that a cured pattern is formed.

At this time, the development can be done by a dipping process, a shower process, a spray process, a brush process, and so on. As a developing solution, aqueous alkali solutions of potassium hydroxide, sodium hydroxide, sodium carbonate, potassium carbonate, sodium phosphate, thorium silicate, ammonia, amines, etc. can be used.

When thermally curable components are contained, it is preferred to further perform thermal curing, for example, by heating to a temperature of from about 140 to about 180° C. Carboxyl groups of a carboxyl group-containing resin react with thermally curable components having two or more cyclic (thio)ether groups in the molecules thereof, so that a cured product superior in various properties such as heat resistance, chemical resistance, moisture absorption resistance, adhesion property, and electrical properties can be formed.

### EXAMPLES

The present invention will be concretely described with reference to the following examples and comparative examples, but the present invention is not limited to the following examples. Unless otherwise stated, “part(s)” and “%” referred to hereinafter are all on a mass basis.

### Synthesis Example 1 of Carboxyl Group-Containing Resin

A 2-liter separable flask equipped with a stirrer, a thermometer, a reflux condenser, a dropping funnel and a nitrogen inlet tube was charged with 660 g of a cresol novolac type epoxy resin (EOCN-104S, softening point: 92° C., epoxy equivalent: 220, produced by Nippon Kayaku Co., Ltd.), 421.3 g of carbitol acetate, and 180.6 g of solvent naphtha, and the mixture was heated and dissolved at 90° C. under stirring.

Subsequently, the resultant was cooled once to 60° C., then 216 g of acrylic acid, 4.0 g of triphenylphosphine, and 1.3 g of methylhydroquinone were added thereto, and the mixture was allowed to react at 100° C. for 12 hours, so that a reaction product having an acid value of 0.2 mg KOH/g was obtained. To the product was added 241.7g of tetrahydrophthalic anhydride, and then it was heated to 90° C. and allowed to react for 6 hours.

Thus, a solution having a solid concentration of 65% of a photosensitive carboxyl group-containing resin having an acid value of solid of 80 mg KOH/g, a double bond equivalent (gram weight of the resin per mole of unsaturated groups) of 400, and a weight average molecular weight of 7,000 was obtained. The solution of the photosensitive carboxyl group-containing resin obtained is hereinafter referred to as A-1 varnish.

### Synthesis Example 2 of Carboxyl Group-Containing Resin

A 2-liter separable flask equipped with a stirrer, a thermometer, a reflux condenser, a dropping funnel and a nitrogen inlet tube was charged with 660 g of a cresol novolac type epoxy resin (EOCN-1045, softening point: 92° C., epoxy equivalent: 220, produced by Nippon Kayaku Co., Ltd.), 443.3 g of carbitol acetate, and 190.0 g of solvent naphtha, and the mixture was heated and dissolved at 90° C. under stirring.

Subsequently, the resultant was cooled once to 60° C., then 216 g of acrylic acid, 4.0 g of triphenylphosphine, and 1.3 g of methylhydroquinone were added thereto, and the mixture was allowed to react at 100° C. for 12 hours, so that a reaction product having an acid value of 0.2 mg KOH/g was obtained. To the product was added 340.0 g of tetrahydrophthalic anhydride, and then it was heated to 90° C. and allowed to react for 6 hours.

Thus, a solution having a solid concentration of 65% of a photosensitive carboxyl group-containing resin having an acid value of solid of 100 mg KOH/g, a double bond equivalent (gram weight of the resin per mole of unsaturated groups) of 450, and a weight average molecular weight of 7,500 was obtained. The solution of the photosensitive carboxyl group-containing resin obtained is hereinafter referred to as A-2 varnish.

### Examples 1 to 11 and Comparative Examples 1 to 3

First, each components shown in Blending Example 1A in the respective ratios (parts by mass) were blended and preliminarily stirred with a stirrer, and thereby a barium sulfate preliminary mixture was prepared. Subsequently, the components shown in Blending Example 1B were blended in the respective ratios (parts by mass) to the barium sulfate preliminary mixture and preliminarily stirred with a stirrer, followed by kneading with a three-roll mill, and thereby a curable resin composition was prepared.

The resultant curable resin composition had a degree of dispersion of 15 μm or less as determined by particle size measurement by using a grind meter manufactured by Erichsen.

TABLE 1

| | | | | | | | | | | | | Comparative | | |
|---|---|---|---|---|---|---|---|---|---|---|---|---|---|---|
| Composition | Example | | | | | | | | | | | Example | | |
| (part(s) by mass) | 1 | 2 | 3 | 4 | 5 | 6 | 7 | 8 | 9 | 10 | 11 | 1 | 2 | 3 |

Blending Example 1A (preliminary mixture)

| A-1 varnish | | 20 | 20 | 20 | 20 | 20 | 20 | 20 | 20 | 20 | 20 | | 20 | 20 | |
|---|---|---|---|---|---|---|---|---|---|---|---|---|---|---|---|
| A-2 varnish | | | | | | | | | | | | 20 | | | 20 |
| Dispersing agent*1 | BYK-111 | 2 | | | | | | | | | | | | | |
| | BYK-145 | | 2 | | | | | | | | | | | | |
| | BYK-2090 | | | 2 | | | | | | | | | | | |
| | BYK-2025 | | | | 3 | | | | | | | | | | |
| | BYK-2164 | | | | | 5 | | | | | | | | | |
| | G-700 | | | | | | 3 | | | | | | | | |
| | SOL-32000 | | | | | | | 3 | | | | 1.5 | | | |
| | SOL-32000 | | | | | | | | 5 | | | | | | |
| | BYK-106 | | | | | | | | | 1 | | | | | |
| | BYK-142 | | | | | | | | | | 5 | | | | |
| | BYK-116 | | | | | | | | | | | | | 5 | |

| | | | | | | | | | | | | | | |
|---|---|---|---|---|---|---|---|---|---|---|---|---|---|---|
| Barium sulfate*2 | 100 | 100 | 100 | 100 | 100 | 100 | 100 | 100 | 100 | 100 | 100 | 100 | 100 | 100 |
| Organic solvent*3 | 10 | 10 | 10 | 10 | 10 | 10 | 10 | 10 | 10 | 10 | 10 | 10 | 10 | 10 |

Preliminary stirring
Blending Example 1B

| A-1 varnish | | 134 | 134 | 134 | 134 | 134 | 134 | 134 | 134 | 134 | 134 | | 134 | 134 | |
|---|---|---|---|---|---|---|---|---|---|---|---|---|---|---|---|
| A-2 varnish | | | | | | | | | | | | 134 | | | 134 |
| Photopolymerization | B-1*4 | 5 | 5 | 5 | 5 | 5 | 5 | 5 | 5 | 5 | 5 | 5 | 5 | 5 | 5 |
| initiator | B-2*5 | 1 | 1 | 1 | 1 | 1 | 1 | 1 | 1 | 1 | 1 | 1 | 1 | 1 | 1 |
| Thermally curable | E-1*6 | 15 | 15 | 15 | 15 | 15 | 15 | 15 | 15 | 15 | 15 | 15 | 15 | 15 | 15 |
| component | E-2*7 | 25 | 25 | 25 | 25 | 25 | 25 | 25 | 25 | 25 | 25 | 25 | 25 | 25 | 25 |
| Thermosetting | Melamine | 5 | 5 | 5 | 5 | 5 | 5 | 5 | 5 | 5 | 5 | 5 | 5 | 5 | 5 |
| catalyst | | | | | | | | | | | | | | | |
| Coloring pigment | F-1*8 | 0.3 | 0.3 | 0.3 | 0.3 | 0.3 | 0.3 | 0.3 | 0.3 | 0.3 | 0.3 | 0.3 | 0.3 | 0.3 | 0.3 |
| | F-2*9 | 0.8 | 0.8 | 0.8 | 0.8 | 0.8 | 0.8 | 0.8 | 0.8 | 0.8 | 0.8 | 0.8 | 0.8 | 0.8 | 0.8 |

| | | | | | | | | | | | | | | |
|---|---|---|---|---|---|---|---|---|---|---|---|---|---|---|
| DPHA*10 | 20 | 20 | 20 | 20 | 20 | 20 | 20 | 20 | 20 | 20 | 20 | 20 | 20 | 20 |
| Silicone-based defoaming agent | 3 | 3 | 3 | 3 | 3 | 3 | 3 | 3 | 3 | 3 | 3 | 3 | 3 | 3 |

Remarks
*1BYK-111 (copolymer containing an acidic group, acid value: 129 mg KOH/g), BYK-145 (phosphate ester of copolymer, acid value: 76 mg KOH/g), BYK-2025 (modified acrylic block copolymer, acid value: 38 mg KOH/g), BYK-2090 (modified polyalkoxylate with acid pigment affinic groups in a star like structure, acid value: 61 mg KOH/g), BYK-2164 (block copolymer, acid value: 0), BYK-106 (polymer salt with an acidic group, acid value: 132 mg KOH/g), BYK-142 (phosphate ester of copolymer, acid value: 46 mg KOH/g), BYK-116 (acrylic copolymer, acid value: 0), (all produced by BYK-Chemie Japan, wetting and dispersing agent DISPERBYK series), G-700 (modified polymer containing a carboxylic acid) (produced by Kyoeisha Chemical Co., Ltd., pigment dispersing agent), SOL-32000 (comb shaped polymer having a basic functional group, acid value: 15 mg KOH/g), SOL-76500 (urethane resin-based comb shaped polymer, acid value: 0), (both are dispersing agents produced by Lubrizol Japan Limited)
*2B-30 (barium sulfate, produced by Sakai Chemical Industry Co., Ltd.)
*3Diethylene glycol monoethyl ether acetate
*4IRGACURE 907 (2-methyl-1-(4-methylthiophenyl)-2-morpholinopropan-1-one, BASF Japan)
*5IRGACURE OXE02 (ethanone, 1-[9-ethyl-6-(2-methylbenzoyl)-9H-carbazol-3-yl]-1-(O-acetyloxime), produced by BASF Japan)
*6DEN-438 (phenol novolac type epoxy resin, produced by The Dow Chemical Company, epoxy equivalent weight: 180)
*7YX4000 (bixylenol type epoxy resin, produced by Mitsubishi Chemical Corporation)
*8C.I. Pigment Yellow 147
*9C.I. Pigment Blue 15: 3
*10KAYARAD (registered trademark) DPHA (dipentaerythritol hexaacrylate, produced by Nippon Kayaku Co., Ltd.)

### Example 12

The respective components shown in Blending Example 2A were blended in the respective ratios (parts by mass) and premixed with a stirrer, and the resulting mixture was pulverized with a bead mill containing beads with a diameter of 0.5 mm (the instrument used: DYNO-MILL, manufactured by Shinmaru Enterprises Corporation) and then filtered through a 3-μm filter, and thereby barium sulfate dispersion liquid 2A was prepared. The pulverization conditions by the bead mill were a beads filling ratio of 90%, a circumferential speed of a rotary blade of 10 m/min, and a liquid temperature of 30° C.

### Blending Example 2A (Barium Sulfate Dispersion Liquid 2A)

Barium sulfate: C 100 parts

Dispersing agent: BYK-180 (wetting and dispersing agent, acid value: 94 mg KOH/g, produced by BYK-Chemie Japan) 2.5 parts

Organic solvent: CA 30 parts

Subsequently, the respective components other than the barium sulfate dispersion liquid 2A shown in Blending Example 2B were blended in the respective ratios (parts by mass) and premixed with a stirrer, followed by kneading with a three-roll mill. While this was stirred with a stirrer, the barium sulfate dispersion liquid 2A was added in the ratio (parts by mass) shown in Blending Example 2B and stirred, and thereby curable resin composition 2B was prepared.

The resultant curable resin composition had a degree of dispersion of 15 μm or less as determined by particle size measurement by using a grind meter manufactured by Erichsen.

### Blending Example 2B (Curable Resin Composition 2B)

A-1 varnish 154 parts (solid content: 100 parts)

Photopolymerization initiator: B-1 5 parts

B-2 1 part

Thermally curable component: E-2 25 parts

E-3 (DEN-431, phenol novolac type epoxy resin, produced by The Dow Chemical Company) 15 parts

Coloring agent: F-1 0.3 parts

F-2 0.1 parts

DPHA: KAYARAD DPHA 20 parts

Thermosetting catalyst: melamine 5 parts

Silicone-based defoaming agent 3 parts

Barium sulfate dispersion liquid 2A: 100 parts

### Example 13

The respective components shown in Blending Example 3A were blended in the respective ratios (parts by mass) and premixed with a stirrer, followed by kneading with a three-roll mill, and thereby resin composition 3A was prepared. The resultant resin composition 3A had a degree of dispersion of 15 μm or less as determined by particle size measurement by using a grind meter manufactured by Erichsen.

### Blending Example 3A (resin composition 3A)

A-1 varnish 154 parts (solid content: 100 parts)

Photopolymerization initiator: B-1 5 parts

B-2 1 part

Barium sulfate: C 100 parts

Thermally curable component: E-2 25 parts

E-3 15 parts

Coloring agent:F-1 0.3 parts

F-2 0.1 parts

DPHA: KAYARAD DPHA 20 parts

Thermosetting catalyst: melamine 5 parts

Silicone-based defoaming agent 3 parts

Next, 5 parts of Disperbyk-2001 (wetting and dispersing agent produced by BYK-Chemie Japan, acid value: 19 mg KOH/g) was added to the resin composition 3A and stirred, so that curable resin composition 3B was prepared.

The resultant curable resin composition 3B had a degree of dispersion of 15 μm or less as determined by particle size measurement by using a grind meter manufactured by Erichsen.

### Example 14

The respective components shown in Blending Example 4 were blended in the respective ratios (parts by mass) and preliminarily mixed with a stirrer, followed by kneading with a three-roll mill, and thereby curable resin composition 4 was prepared. The resultant curable resin composition 4 had a degree of dispersion of 15 μm or less as determined by particle size measurement by using a grind meter manufactured by Erichsen.

### Blending Example 4 (Curable Resin Composition 4)

A-1 varnish 154 parts (solid content: 100 parts)

Photopolymerization initiator: B-1 5 parts

B-2 1 part

Barium sulfate: C 100 parts

Thermally curable component: E-2 25 parts

E-3 15 parts

Dispersing agent: DISPERBYK-111

*1 2 parts

Coloring agent:F-1 0.3 parts

F-2 0.1 parts

DPHA: KAYARAD DPHA 20 parts

Thermosetting catalyst: melamine 5 parts

Silicone-based defoaming agent 3 parts

Organic solvent DPM (dipropylene glycol monomethyl ether) 5 parts

### Evaluation of Performance:

### <Optimal Irradiation Intensity>

Each of the curable resin compositions of Examples 1 to 14 and Comparative Examples 1 to 3 is applied by screen printing to the entire surface of a substrate with a circuit pattern having a copper thickness of 35 μm, which has previously been polished with buff rolls, washed with water, and dried, and the resulting film was dried in a hot air-circulating drying oven of 80° C. for 60 minutes. After drying, each of the samples was exposed to light through a step tablet (Kodak No. 2) by using a direct imaging apparatus equipped with a semiconductor laser having a maximum wavelength of 355 nm, a direct imaging aligner equipped with a high-pressure mercury lamp, or an aligner equipped with a high-pressure mercury lamp, and then was developed for 90 seconds under a condition of a spray pressure of 0.2 MPa using a 1% by mass aqueous sodium carbonate solution of 30° C., and the exposure quantity at which the residual pattern of the step tablet had seven steps was considered to be the optimal irradiation intensity.

### <Breakpoint>

Each of the curable resin composition of Examples 1 to 14 and Comparative Examples 1 to 3 was applied to have a thickness of about 25 μm by screen printing to a solid substrate and then dried in a hot air-circulating drying oven of 80° C. for 30 minutes. After the drying, the substrate was left at rest to room temperature and then was developed. Negatives were developed under a condition of a spray pressure of 0.2 MPa using a 1% by mass aqueous sodium carbonate solution of 30° C. and the time taken until the dry coating film was removed completely was measured with a stopwatch.

### <Resolution>

Each of the curable resin compositions of Examples 1 to 14 and Comparative Examples 1 to 3 was applied by a screen printing process to a circuit pattern substrate with a line/space of 300/300 and a copper thickness of 35 μm prepared by grinding with a buff roll, washing with water, and drying, and then it was dried in a hot air-circulating drying oven of 80° C. for 30 minutes. After the drying, light was applied using a direct imaging apparatus equipped with a semiconductor laser having a maximum wavelength of 355 nm.

As an exposure pattern, a direct imaging data for drawing lines of 50/60/70/80/90/100 μm in space portions was used. As to irradiation intensity, active energy rays were applied so that it might become the optimal irradiation intensity of the curable resin composition. After the exposure, development was performed for 90 seconds at a spray pressure of 0.2 MPa using a 1% by mass aqueous sodium carbonate solution of 30° C., thereby forming a pattern, and then thermal curing of 150° C.×60 minutes was carried out, and thereby a cured coating film was obtained.

The minimum remaining line of the resulting cured coating film of the curable resin composition was measured by an optical microscope adjusted to 200 magnifications.

### <Through Hole Developability>

In a 1.0 mm thick copper-clad laminate through holes were formed with a φ300 μm drill and then through hole plating was performed by a conventional method, so that a substrate with 100 through holes each having an actually measured diameter of 260 μm was produced. Each of the curable resin compositions of Examples and Comparative Examples was printed twice by screen printing, dried in a hot air-circulating drying oven of 80° C. for 30 minutes, and then allowed to cool to room temperature. The substrate was developed for 90 seconds at a spray pressure of 0.2 MPa using a 1% by mass aqueous sodium carbonate solution of 30° C. and then washed with water, and thereby a substrate after development was obtained. The inside of a through hole of the resulting substrate was inspected by eyes and by a scope, and when a residue remained, the above-described steps were repeated, and thereby the developability within the through hole was evaluated. The judgment criteria are as follows.

⊙: Development of 100% through holes can be done by performing one cycle of development.

◯: Development of 100% through holes can be done by performing two cycles of development.

Δ: Development of 100% through holes can be done by performing three cycles of development.

×: Development of through holes cannot be done even if three cycles of development are performed.

### Property Tests:

### (Preparation of Substrate for Evaluation)

Each of the compositions of Examples 1 to 14 and Comparative Examples 1 to 3 was applied to the entire surface of a patterned copper foil substrate by screen printing, then dried at 80° C. for 20 minutes, and then allowed to cool to room temperature. This substrate was irradiated with light in a solder resist pattern at an optimal irradiation intensity by using a direct imaging apparatus equipped with a semiconductor laser having a maximum wavelength of 355 nm and then developed by spraying a 1% aqueous Na₂CO₃ solution of 30° C. at a spray pressure of 0.2 MPa for 90 seconds, and thereby a resist pattern was obtained. The substrate was irradiated with ultraviolet rays under a condition of an integrated irradiation intensity of 1000 mJ/cm² in a UV conveyor oven and then cured by heating at 150° C. for 60 minutes. As to the resulting printed wiring board (substrate for evaluation), properties were evaluated as follows.

### <Solder Heat Resistance>

A substrate for evaluation to which a rosin-based flux had been applied was immersed in a solder bath adjusted to 260° C. beforehand and subsequently the flux was washed away with denatured alcohol; then, blister and peeling of the resist layer were evaluated visually. The judgment criteria are as follows.

◯: Peeling is not observed even if 10-second immersion is repeated three times or more.

Δ: Peeling occurs a little if 10-second immersion is repeated three times or more.

×: Blister and peeling occur in the resist layer within three or less cycles of 10-second immersion.

### <Electroless Gold Plating Resistance>

Using a commercially available electroless nickel plating bath and a commercially available electroless gold plating bath, plating was carried out under the conditions of 0.5 μm nickel and 0.03 μm gold. After evaluation of the presence of blister of the resist layer and the presence of permeation of plating, the presence of blister of the resist layer was evaluated by tape peeling. The judgment criteria are as follows.

◯: Peeling does not occur after the tape peeling.

Δ: Slight permeation is observed after the plating and blister is also observed after the tape peeling.

×: Peeling is observed after the plating.

### <Electrical Property>

A substrate for evaluation was prepared under the above-described conditions using a comb-shaped electrode pattern of line/space=50/50 μm instead of the copper foil substrate. To the comb-shaped electrode was applied a bias voltage of DC 10 V under the conditions of 130° C. and 85% R.H., and an insulation resistance value after lapse of 100 hours was measured in a bath. The measurement was carried out at a voltage of DC 10 V.

### <Acid Resistance>

A substrate for evaluation was immersed in a 10% by mass aqueous sulfuric acid solution for 30 minutes at room temperature, and thereby permeation or elution of the coating film and peeling by tape peeling were checked. The judgment criteria are as follows.

◯: There is no permeation, elution, or peeling.

Δ: Slight permeation, elution or peeling is observed.

×: Permeation, elution or peeling is observed greatly.

### <Maximum Development Life>

Each of the curable resin compositions of Examples and Comparative Examples was applied to the entire surface of a patterned copper foil substrate by screen printing and then dried at 80° C. while the substrate was taken out at every 10 minutes during a period of from 20 minutes to 80 minutes, and then it was allowed to cool to room temperature. This substrate was developed for 60 seconds at a spray pressure of 0.2 MPa using a 1% by mass aqueous sodium carbonate solution of 30° C., and the maximum permissible drying time in which no residue remained was defined as a maximum development life.

### Example 15

### Dry Film Evaluation:

### <Dry Film Preparation>

After diluting the curable resin composition of Example 1 with methyl ethyl ketone appropriately, it was applied to a PET film (produced by Toray Industries, FB-50, 16 μm) so that the thickness after drying might become to 20 μm, and then it was dried at 80° C. for 30 minutes, and thereby a dry film was obtained.

### <Substrate Preparation>

After buffing a patterned copper foil substrate, a dry film prepared by the above-described method was heat-laminated under the conditions of degree of pressurization: 0.8 MPa, 70° C., one minute, and a degree of vacuum: 133.3 Pa by using a vacuum laminator (manufactured by Meiki Co., Ltd., MVLP (registered trademark) -500), and thereby a substrate (unexposed substrate) with an unexposed solder resist layer (dry coating film) was obtained.

As to the resulting test substrate with a cured film, respective evaluation tests were carried out according to the testing methods and the evaluating methods.

The results of the evaluation tests are shown in Table 2.

TABLE 2

| | | | | | | | | | | | | | | | | Comparative | | |
|---|---|---|---|---|---|---|---|---|---|---|---|---|---|---|---|---|---|---|
| | Example | | | | | | | | | | | | | | | Example | | |
| Characteristics | 1 | 2 | 3 | 4 | 5 | 6 | 7 | 8 | 9 | 10 | 11 | 12 | 13 | 14 | 15 | 1 | 2 | 3 |
| Solder resist | L | L | L | L | L | L | L | L | L | L | L | L | L | L | D | L | L | L |
| form | | | | | | | | | | | | | | | | | | |
| (D: dry film, L: | | | | | | | | | | | | | | | | | | |
| liquid) | | | | | | | | | | | | | | | | | | |
| Optimal | 150 | 150 | 150 | 180 | 150 | 150 | 150 | 150 | 150 | 150 | 200 | 150 | 150 | 150 | 100 | 150 | 160 | 200 |
| irradiation | | | | | | | | | | | | | | | | | | |
| intensity (mJ/ | | | | | | | | | | | | | | | | | | |
| cm²) | | | | | | | | | | | | | | | | | | |
| Breakpoint | 15 | 15 | 15 | 17 | 18 | 16 | 15 | 15 | 16 | 16 | 11 | 16 | 18 | 18 | 15 | 23 | 22 | 18 |
| (sec.) | | | | | | | | | | | | | | | | | | |
| Resolution (μm) | 50 | 50 | 50 | 50 | 50 | 50 | 50 | 50 | 50 | 50 | 70 | 50 | 50 | 50 | 50 | 70 | 70 | 80 |
| Through hole | ⊙ | ⊙ | ⊙ | ◯ | ◯ | ⊙ | ⊙ | ⊙ | ◯ | ◯ | ⊙ | ⊙ | ◯ | ◯ | ⊙ | Δ | X | ◯ |
| developability | | | | | | | | | | | | | | | | | | |
| Solder heat | ◯ | ◯ | ◯ | ◯ | ◯ | ◯ | ◯ | ◯ | ◯ | ◯ | ◯ | ◯ | ◯ | ◯ | ◯ | ◯ | Δ | Δ |
| resistance | | | | | | | | | | | | | | | | | | |
| Electroless | ◯ | ◯ | ◯ | ◯ | ◯ | ◯ | ◯ | ◯ | ◯ | ◯ | Δ | ◯ | ◯ | ◯ | ◯ | ◯ | Δ | Δ |
| gold plating | | | | | | | | | | | | | | | | | | |
| resistance | | | | | | | | | | | | | | | | | | |
| Electrical | 2 | 3 | 4 | 4 | 8 | 3 | 7 | 9 | 9 | 2 | 2 | 2 | 5 | 4 | 3 | 5 | 5 | 4 |
| property | | | | | | | | | | | | | | | | | | |
| (×10⁷Ω) | | | | | | | | | | | | | | | | | | |
| Acid resistance | ◯ | ◯ | ◯ | ◯ | ◯ | ◯ | ◯ | ◯ | ◯ | ◯ | ◯ | ◯ | ◯ | ◯ | ◯ | ◯ | Δ | ◯ |
| Maximum | 60 | 60 | 70 | 70 | 60 | 60 | 80 | 70 | 60 | 70 | 70 | 60 | 60 | 60 | — | 60 | 60 | 70 |
| development | | | | | | | | | | | | | | | | | | |
| life (min.) | | | | | | | | | | | | | | | | | | |

As shown in Table 2, in the cases of Examples through 15 in which barium sulfate was surface treated with the dispersing agent according to this embodiment, the good developability of through holes, and superior resolution, solder heat resistance, and electroless gold plating resistance were achieved. In contrast, in Comparative Example 1 having no dispersing agent, and in Comparative Example 2 having a dispersing agent other than the dispersing agent of this embodiment, satisfactory through hole developability was not achieved.

What is claimed is:

1. A curable resin composition comprising a carboxyl group-containing resin, a photopolymerization initiator, and barium sulfate surfaced with a dispersing agent having an acidic group and/or a dispersing agent having at least any of a block copolymer, a grafted polymer, and a star polymer structure.

2. The curable resin composition according to claim 1, wherein the carboxyl group-containing resin has at least one or more ethylenic unsaturated group in its molecule.

3. A dry film comprising a dry coating film obtained by applying the curable resin composition according to claim 1 or 2 to a film and then drying it.

4. A cured product obtainable by photocuring, by application of active energy rays, a dry coating film formed on a substrate by applying the curable resin composition according to claim 1 or 2 to the substrate and then drying it or by laminating a dry film obtained by applying the curable resin composition to a film and drying it.

5. A printed wiring board having a pattern of a cured product obtainable by photocuring, by application of active energy rays, a dry coating film formed on a substrate by applying the curable resin composition according to claim 1 or 2 to the substrate and then drying it or by laminating a dry film obtained by applying the curable resin composition to a film and drying it.
